(19) United States
(12) Patent Application Publication
(10) Pub. No.: US 2013/0276887 A1
(43) Pub. Date: Oct. 24, 2013

(54) Functionalized Semiconducting Polymers For Use In Organic Photovoltaic Devices

(71) Applicants: Brian Worfolk, Edmonton (CA); Jillian Buriak, Edmonton (CA); David Rider, White Rock (CA); Kenneth Harris, Edmonton (CA)

(72) Inventors: Brian Worfolk, Edmonton (CA); Jillian Buriak, Edmonton (CA); David Rider, White Rock (CA); Kenneth Harris, Edmonton (CA)

(21) Appl. No.: 13/906,147

(22) Filed: May 30, 2013

Related U.S. Application Data
(63) Continuation of application No. PCT/CA2011/000723, filed on Jun. 21, 2011.
(60) Provisional application No. 61/418,231, filed on Nov. 30, 2010.

(51) Int. Cl. H01L 51/00; H01L 51/44

(52) U.S. Cl. CPC H01L 51/0037; H01L 51/441
USPC 136/263; 524/548; 438/93

(57) ABSTRACT

The present invention is directed to functionalized semiconducting polymers (FSPs) having the following general formula (I): wherein PB is a semiconducting polymer backbone, L is an alkyl, alkenyi or alkoxy chain and CTG is a cationic terminal group. The FSPs may be used as interfacial modifiers in organic electronics, and more specifically organic photovoltaic devices.

### CROSS-REFERENCE TO RELATED APPLICATIONS

This application claims the benefit of U.S. Provisional Patent Application U.S. Ser. No. 61/418,231 filed Nov. 30, 2010, the contents of which are herein incorporated by reference in its entirety.

### FIELD OF THE INVENTION

The present invention is directed to functionalized semiconducting polymers (FSPs) for use as interfacial modifiers in organic electronics, more specifically organic photovoltaic devices.

### BACKGROUND OF THE INVENTION

Inorganic photovoltaic devices tend to be expensive to manufacture and thus are generally not sufficiently cost-effective for widespread deployment as an alternate electricity producing method to conventional electricity production systems. In addition to the high cost, inorganic photovoltaic devices are typically heavy and brittle and require significant infrastructure for installation. As a result, purchasing inorganic photovoltaic devices requires a significant amount of time before the investment produces a return. Organic photovoltaic devices (OPVs) hold the potential to be much less expensive and include functional advantages such as colour tunability and the potential for flexible products. Despite the significant advantages to OPV technology, OPVs currently lack sufficient performance and stability for successful commercialization. As a result, there is a need for more efficient and lower cost organic photovoltaic systems.

OPVs typically operate by absorbing sunlight and creating energetic particles known as excitons. These excitons consist of strongly interacting pairs of electrons and holes, which are treated as single bound particles. In order to extract electrical energy from excitons, the excitons must first migrate to an interface that is capable of separating their component charges. Once separated, the electrons and holes are transported to electrodes where they are extracted from the photovoltaic device to produce an electrical current.

Polymer OPVs typically employ a two-component active layer consisting of an electron-donating conjugated polymer and an electron-accepting fullerene, structured in a disordered bicontinuous interpenetrating network known as the bulk heterojunction (BHJ). A widely researched polymer-based OPV device employs a photoactive BHJ of regioregular 2,5-diyl-poly(3-hexylthiophene) (P3HT) and [6,6]-phenyl-C₆₁-butyric acid methyl ester (PCBM). In this excitonic polymer OPV configuration, the absorption of light generates bound electron—hole pairs (i.e., excitons) that ideally dissociate into free charge carriers at the P3HT-PCBM (donor-acceptor) interface.

In order to increase cell efficiency, interfacial modifiers (IMs) are applied at each of the electrodes, and these IMs reduce the energy required to extract charge carriers from the device. IMs that accomplish this task more effectively are expected to improve electrical current output, increase open-circuit voltage and render the devices more efficient.

In conventional polymer OPVs, which operate in “forward mode” (FIG. 3), the free electron and hole charge carriers migrate from the donor-acceptor interface to a low work function electrode (e.g., a reflective metal such as Al) and a high work function electrode (e.g., a transparent conducting oxide, such as indium tin oxide (ITO)), respectively.

Operating a polymer BHJ OPV device in an “inverted mode” (FIG. 3), where electrons are extracted from the transparent electrode and holes from the reflective electrode, generally requires tailoring of the electrode work functions using interfacial modifiers, but is often advantageous with respect to performance stability, design flexibility, and compatibility with stacked and/or tandem architectures.

Sodium poly(3,4-ethylenedioxythiophene):poly(p-styrenesulfonate) [(PEDOT:PSS)⁻Na⁺] is an organic polymer blend of cationic, conducting PEDOT that is charge over-compensated by anionic, insulating PSSNa. This polymer blend is usually applied in organic electronics (including forward mode polymer OPVs) as a hole collecting interfacial modification layer on ITO due to its stable and high work function. A (PEDOT:PSS)⁻Na⁺ interfacial layer also leads to a smoother electrode with improved ohmic contact with the active layer, enhanced hole collection, increased open-circuit voltage (V_{oc}), as well as improved areal electrical uniformity in completed OPV devices. In fact, anionic (PEDOT:PSS) has been deposited with cationic poly(p-xylene-α-tetrahydrothiophenium) using electrostatic layer-by-layer (LbL) to produce an ITO modifier to control electron leakage in polymer light-emitting diodes. While (PEDOT:PSS)⁻Na⁺ is a ubiquitous material in organic electronics, it is not normally applied to ITO in inverted OPVs due to its electron-blocking properties.

The use of an interfacial modifier in inverted OPVs is key to fabricating devices with optimal device efficiency and stability. As such, a low work function alternative to PEDOT:PSS is required to successfully modify ITO for use as a cathode in inverted OPVs. To date, this surface modification has been successfully demonstrated using only inorganic or surface-functionalized inorganic materials. The reduction of the work function of ITO with purely organic polymer coatings for inverted OPVs is largely unexplored and is attractive from several standpoints. For example, many organic polymers can be tailored to match the electronic, morphological and physical requirements for improved device performance. In addition, solution-processable polymers are desirable from an industrial perspective as costly vacuum deposition equipment is avoided, and in a further refinement, water-soluble polymers are particularly advantageous as organic solvents are relatively expensive and environmentally harmful. The quality and uniformity of polymer coatings is often higher than those of inorganic counterparts and the use of these coatings leads to improved mechanical flexibility and robustness of the overall device compared to devices made from inorganic materials. In addition, polymers are amenable to electrostatic multilayer approaches whereby nanoscale material can be deposited one layer-at-a-time in order to fabricate multilayer films of precise thickness. The electrostatic multilayer assembly of water-soluble interfacial modification polymers on ITO is therefore an attractive complement.

A review of the prior art reveals various known polymers and multilayer fabrication methods used to affect the electronic properties of substrates. Buriak et al. (Adv. Funct. Mater. 2010, 20, 2404-2415) discloses the synthesis of a cationic and water-soluble polythiophene ([poly[3-(6-pyridiniumylhexyl)thiophene bromide]) and its use in hybrid coatings on indium tin oxide (ITO). Rubner et al. (Macromolecules 1997, 30, 2712-2716; J. Appl. Phys. 79 (10) 15 May 1996) discloses the fabrication of light-emitting diodes based on self-assembled multilayers of poly(phenylene vinylene) as well as multilayer fabrication using polyaniline. Friend et al. (Nature vol 404 Mar. 30, 2000, 481-494) discloses molecular-scale interface engineering for polymer light-emitting diodes using poly (p-phenylene vinylene) (PPV) and poly (p-xylylene-a-tetrahydrothiophenium) (PXT) along with PEDOT:PSS.

### SUMMARY OF THE INVENTION

In accordance with the invention, there is provided functionalized semiconducting polymer (FSP) compounds and methods for multilayer fabrication of interfacial modifiers. The interfacial modifiers may be used in organic electronics and more specifically organic photovoltaic devices.

More specifically, there is provided functionalized semiconducting polymers with the following generalized structure:

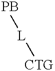

wherein PB is a polymer backbone selected from a number of semiconducting polymers, L is an alkyl, elkenyl or alkoxy chain of varying length and CTG is a cationic terminal group selected from a quaternary ammonium cation providing a net positive charge in aqueous solutions or

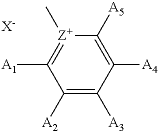

where Z is either nitrogen or phosphorus, A1 to A5 are each independently selected from a variety of possible substituents and where X is a counterion.

In another embodiment, the functionalized semiconducting polymer may be of the following generalized structure:

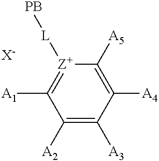

wherein PB is a polymer backbone selected from a number of semiconducting polymers, L is an alkyl, elkenyl or alkoxy chain of varying length, and Z is either nitrogen or phosphorus and A1 to A5 are each independently selected from a variety of possible substituents and where X is a counterion.

In another embodiment of the invention, A1-A5 are not all hydrogen, the polymer backbone is not polythiophene and the linker L is not a C6 alkyl.

In a further embodiment of the invention, the semiconducting polymer backbone is chosen from polythiophene, polyacetylene, PBDTTPD, PCDTPT, PDTSTPD, and PSBTBT.

In other embodiments, L is a C3-C8 alkyl, alkoxy or alkenyl.

In further embodiments, there is provided a semiconducting polymer wherein Z is either nitrogen or phosphorus.

In yet another embodiment, A3, A4 and A5 are independently selected from hydrogen, cyano, phenyl, C1-C8 alkoxy, C1-C8 linear or branched alkyl optionally substituted with one or two phenyl groups, carbamate, C1-C6 linear or branched alkyl ester optionally substituted with one or two phenyl groups, and 7-hexyl-benzo[lmn][3,8]phenanthrolin-2-yl-1,3,6,8-tetraone.

In another embodiment, A3, A4 and A5 are hydrogen and/or L is C6 alkyl.

In further embodiments, the functionalized semiconducting polymer is selected from any one of:
2,5-diyl-poly[3-(6-(4-methoxy pyridiniumyl)-hexyl)thiophene] (P3(MOP)HT);
2,5-diyl-poly[3-(6-(3-cyano pyridiniumyl)-hexyl)thiophene] (P3(CNP)HT);
2,5-diyl-poly[3-(6-(4-tert-butylpyridiniumyl)-hexyl)thiophene] (P3(TBP)HT);
2,5-diyl-poly[3-(6-(4-boc-amino pyridiniumyl)-hexyl)thiophene] (P3(BAP)HT);
2,5-diyl-poly[3-(6-(4-phenylpyridiniumyl)-hexyl)thiophene] (P3(4PP)HT;
2,5-diyl-poly[3-(6-(4-(diphenylmethyl)pyridiniumyl)-hexyl)thiophene] (P3(DPMP)HT;
2,5-diyl-poly[3-(6-(3-phenylpyridiniumyl)-hexyl)thiophene] (P3(3PP)HT;
2,5-diyl-poly[3-(6-(4-(7-hexyl-benzo[Imn][3,8]phenanthrolin-2-yl-1,3,6,8-tetraone)pyridiniumyl)-hexyl)thiophene] (P3(HBPTP)HT); and
2,5-diyl-poly[3-(6-(4-(3-phenylpropyl)pyridiniumyl)-hexyl)thiophene] (P3(PPP)HT).

In another aspect of the invention, there is provided a method for forming an interfacial modifier comprising the step of forming a polymer hybrid with a functionalized semiconducting polymer and (PEDOT:PSS)⁻ or a functional equivalent thereof.

In another embodiment, the polymer hybrid is formed by electrostatic layer-by-layer (LbL) assembly with a solution of a functionalized semiconducting polymer and any colloidal suspension of (PEDOT:PSS)⁻ or a functional equivalent thereof.

In another embodiment, the polymer hybrid is formed using an electrochemically prepared (PEDOT:PSS)⁻ film on a conductive substrate.

In another embodiment, the polymer hybrid is formed using an electrochemically prepared (PEDOT:PSS)⁻ film on indium tin oxide (ITO).

In another aspect the invention provides an organic photovoltaic device comprising a cathode including an interfacial modifier prepared by either the LbL or electrochemical method.

In yet another aspect, there is provided a method of forming an interfacial modifier by layer by layer (LbL) deposition comprising the steps of:

a) applying a functionalized semiconducting polymer (FSP⁺) to a conductive electrode to form a first half bilayer;
b) applying (PEDOT:PSS)⁻ Na⁺ or a functional equivalent thereof to the first half bilayer to yield a first bilayer comprising a (PEDOT:PSS)⁻ film on the first half bilayer; and,
c) repeating steps a) and b) to a desired number of bilayers.

In various embodiments, steps a)-c) are an electrostatic deposition process and/or steps a)-c) are repeated to produce an interfacial modifier having a desired optical density.

In yet another aspect, there is provided a method of forming an interfacial modifier by layer by layer (LbL) deposition comprising the steps of:

a) applying (PEDOT:PSS)⁻ Na⁺ or a functional equivalent thereof electrochemically to a conductive electrode to yield a first half bilayer;
b) applying a functionalized semiconducting polymer (FSP⁺) of any one of claims 1-18 to the first half bilayer to form a first bilayer;
c) repeating steps a) and b) to a desired number of bilayers.

In another embodiment of the method step a) is an electrochemical deposition process initiated on thienylsilane-modified ITO.

### BRIEF DESCRIPTION OF THE DRAWINGS

The invention is described with reference to the drawings in which:

FIG. 1 shows a schematic representation of the quaternization reaction to form P3RHT⁺Br⁻.

FIG. 2 shows the UV/visible light absorbance of certain derivative polymers in 95:5 (v/v) H₂O:DMF solvent.

FIG. 3 shows a schematic representation of forward mode and inverted mode bulk heterojunction photovoltaic devices.

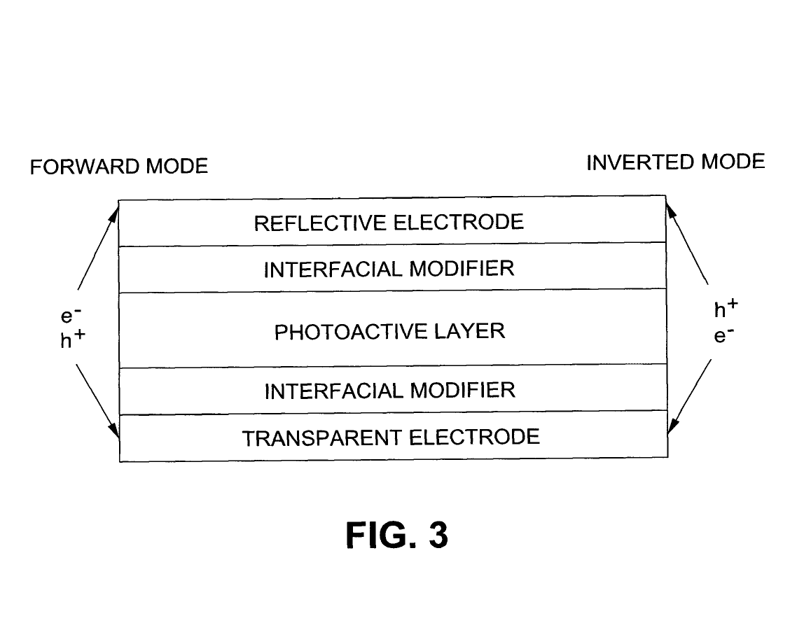

FIG. 4 shows two alternative embodiments of a scheme to assemble hybrid interfacial modifiers.

FIG. 5 shows a schematic representation of the intertwined polymers forming a hybrid interfacial modifier; dashed lines show the bilayer separation. It is not intended to show the exact macromolecular morphology.

FIG. 6 is a graph showing optical absorbance of (P3RHT/cPEDOT:PSS)ₙ films having different number of bilayers (n). (P3RHT denotes a polythiophene derivative)

FIG. 7 is a graph showing (P3RHT/cPEDOT:PSS)ₙ film thickness increases as a result of increasing number of bilayers.

FIG. 8 is a schematic representation for the modification of ITO/(ePEDOT:PSS)⁻Na⁺ with P3RHT⁺Br⁻.

FIG. 9 shows the band energies for certain polymers resulting from cyclic voltammetry analysis of polymer films.

FIG. 10 shows representative current-density/voltage curves for an OPV devices fabricated using a number of thiophene derivatives for the interfacial modifier.

FIG. 11 is a table of OPV device performance parameters for three selected interfacial modifiers.

### DETAILED DESCRIPTION OF THE INVENTION

The invention relates to novel polymers for use as interfacial modifiers in organic photovoltaic devices. When describing the present invention, all terms not defined herein have their common art-recognized meanings. To the extent that the following description is of a specific embodiment or a particular use of the invention, it is intended to be illustrative only, and not limiting of the claimed invention. The following description is intended to cover all alternatives, modifications and equivalents that are included in the spirit and scope of the invention, as defined in the appended claims.

In accordance with the invention, functionalized semiconducting polymers (FSPs) of the following general formula are described:

PB-L-CTG (1)

in which PB is a semiconducting polymer backbone, L is a linker group and CTG is a cationic terminal group electrically compensated by a mobile anion.

More specifically, the invention describes compounds of the formula:

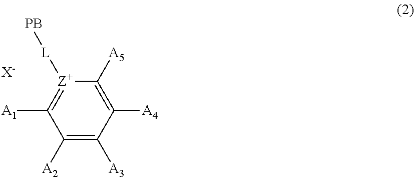

in which PB is a semiconducting polymer backbone selected from any one of poly(p-phenylene vinylene) (PPV; K), poly(benzodithiophene-alt-[3,4-c]thienopyrrole-4,6-dione) (PBDTTPD; L), poly(2,7-carbazole-alt-5,5-di-2-thienylbenzothiadiazole (PCDTBT; M), poly(thieno[3,4-b]thiophene-alt-benzodithiophene) (PTB(1-8); N), poly(fluorene-alt-bithiophene) (FT2; O), poly(dithienosilole-alt-[3,4-c]thienopyrrole-4,6-dione) (PDTSTPD; P), poly(dithieno(3,2-b:2′,3′-d)silole)-alt-benzothiadiazole) (PSBTBT; Q) and poly(1,4-diketopyrrolopyrrole) (DPP; R) or functional derivatives thereof or where PB is any one of polythiophene or polyacetylene or functional derivatives thereof;
and wherein L is a single bond, C, C2-C14 alkyl, alkenyl or alkoxy linear or branched chain, Z is either nitrogen or phosphorus, A₁, A₂, A₃, A₄ and A₅ are each independently selected from hydrogen, cyano, phenyl, C1-C10 alkoxy, a C1-C10 linear or branched alkyl optionally substituted with one or two phenyl groups, carbamate, a C1-C10 linear or branched alkyl ester optionally substituted with one or two phenyl groups, and 7-hexyl-benzo[lmn][3,8]phenanthrolin-2-yl-1,3,6,8-tetraone or functional equivalents thereof;
X is a counterion maintaining charge neutrality and will typically be a halide, sulphate, sulphonate, carboxylate, perchlorate, nitrate, carbonate, hydroxide, benzoate, tolsylate, acetate or functional equivalents thereof. The overall arrangement of the functional groups is either regiorandom or regioregular.

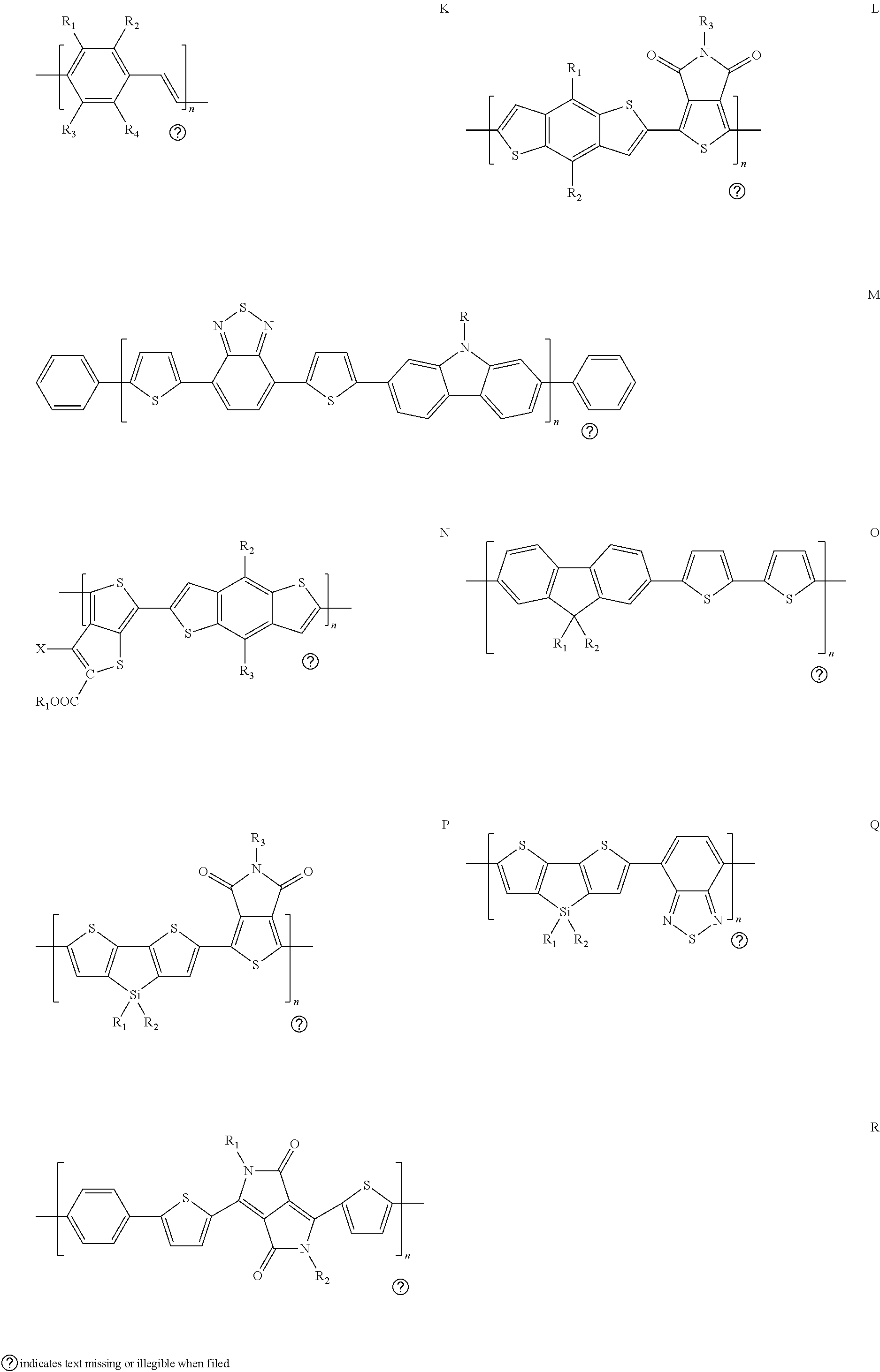

The polymer backbone can include various types of semiconducting polymers such as polythiophene, polyacetylene, (PPV), (PBDTTPD), (PCDTBT), (PTB(1-8)), (FT2), (PDTSTPD),) (PSBTBT) and (DPP) or functional derivatives thereof. These organic semiconductors are generally conjugated materials that have an electronic gap in the range between 0.1-0.3 eV and show semiconductor-type conductivity in various devices. The number of repeat monomer units, n on the polymer backbone is typically 1-10000, or 1-9000, or 1-8000, or 1-7000, or 1-6000, or 1-5000, or 1-4000, or 1-3000, or 1-2000, or 1-1000, or 1-500 although longer polymers may also be used.

In accordance with one embodiment of the invention, the polymer backbone is polythiophene. Polythiophenes typically have alkyl, alkoxy or alkenyl chains bonded to the main polymer backbone in either a regiorandom or regioregular arrangement. The alkyl, alkoxy or alkenyl chains impart solubility to the polymer in organic solvents rendering them processable for solution cast thin films. If the terminal group of the alkyl, alkoxy or alkenyl chain is cationic or anionic, the polymer tends to be soluble in aqueous solutions. The alkyl, alkoxy or alkenyl chain length can vary between a single carbon (C1) and 14 carbons (C14).

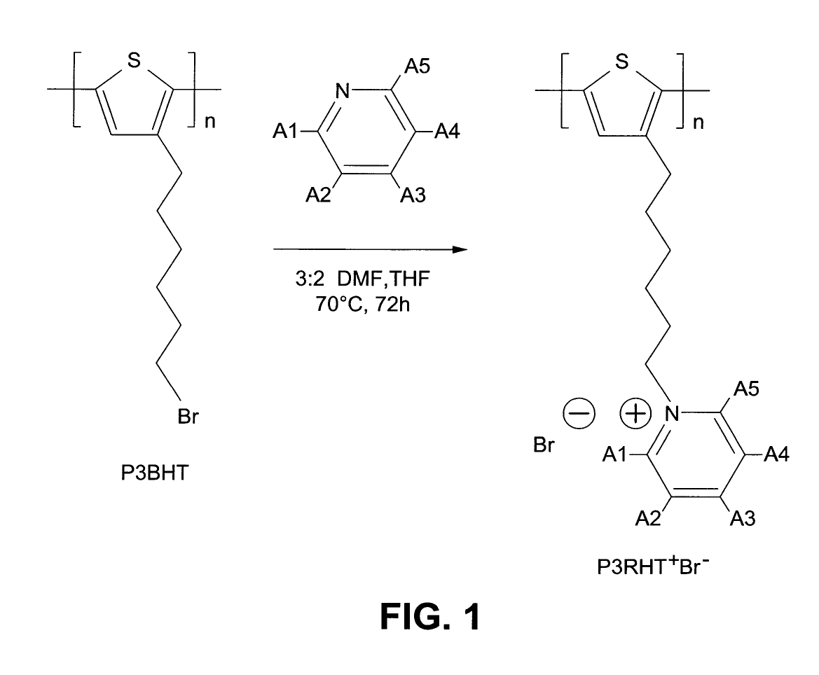

The most common alkyl, alkoxy or alkenyl chain lengths typically vary between C4 and C8 but can encompass other functionally equivalent substituents. For example, the alkyl, alkoxy or alkenyl chain length is determined by the poly-3-bromoalkylthiophene (P3BAT) precursor where the alkyl, alkoxy or alkenyl chain length can be varied such that the quaternization reaction is used to synthesize the cationic polymer with a broad range of possible alkyl, alkoxy or alkenyl chain lengths (FIG. 1—note P3BAT is shown with the hexyl side chain (P3BHT) for example).

The charge on the polymer is balanced by a counterion that exists in solution with the polymer. The counterion can be a halide, sulphate, sulphonate, carboxylate, perchlorate, nitrate, carbonate, hydroxide, benzoate, tolsylate, or acetate or functional equivalents thereof. Typical counterion halides are bromide, chloride, and iodide.

The cationic terminal group (CTG) of the polymer is typically a pyridiniumyl group. Alternatively, phosphorus can be in the ring instead of nitrogen. In addition, any quaternary ammonium compound that provides a net positive charge in aqueous solutions can be used as the CTG.

In various embodiments, the groups attached to the cationic terminal group at the A3, A4, and A5 positions can be independently selected from hydrogen, cyano, phenyl, C1-C8 alkoxy, C1-C8 linear or branched alkyl optionally substituted with one or two phenyl groups, carbamate C1-C6 linear or branched alkyl ester optionally substituted with one or two phenyl groups, and 7-hexyl-benzo[lmn][3,8]phenanthrolin-2-yl-1,3,6,8-tetraone or functional equivalents thereof.

In various embodiments in which the polymer backbone is polythiophene, the invention comprises polymer derivatives having the following general formula:

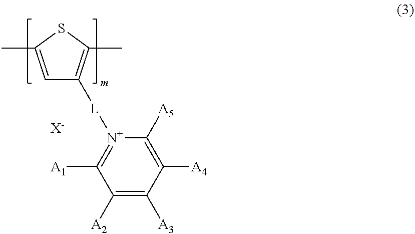

wherein the CTG contains either nitrogen N or phosphorus P, L is a single bond, C, or C2-C14 alkyl, alkoxy or alkenyl chain, A₁, A₂, A₃, A₄ and A₅ are each independently selected from the group consisting of hydrogen, cyano, phenyl, C1-C6 alkoxy, C1-C6 linear or branched alkyl optionally substituted with one or two phenyl groups, carbamate, C1-C6 linear or branched alkyl ester optionally substituted with one or two phenyl groups, and 7-hexyl-benzo[lmn][3,8]phenanthrolin-2-yl-1,3,6,8-tetraone or functional equivalents thereof. X is a counterion that accompanies the polymer in order to maintain electric neutrality.

In other embodiments, the invention comprises polymer derivatives in which L is a C3-C8 alkyl or alkenyl chain. This range is expected to be the most suitable range of alkyl chain lengths providing sufficient solubility of the polymer in aqueous solutions while retaining the desirable physical properties for their application as interfacial modifiers. As noted, it is understood that single and double bonds and alkoxy groups may reside on the side chain (alkyl, alkenyl or alkoxy) in any number and order if functionality is maintained.

In one embodiment, L is a C6 alkyl. This is the chain length that originates from the P3BHT precursor and is native to the ubiquitous poly-3-hexylthiophene P3HT polymer used in many organic devices. It is understood that C6 is the most likely chain length to be used in this invention although as noted above other chain lengths can be used as well.

In other embodiments, the functionalized semiconducting polymers (FSPs) are specific derivatives of formula (3):
2,5-diyl-poly[3-(6-(4-methoxy pyridiniumyl)-hexyl)thiophene] (P3(MOP)HT; B),
2,5-diyl-poly[3-(6-(3-cyano pyridiniumyl)-hexyl)thiophene] (P3(CNP)HT; C),
2,5-diyl-poly[3-(6-(4-tert-butylpyridiniumyl)-hexyl)thiophene] (P3(TBP)HT; D),
2,5-diyl-poly[3-(6-(4-boc-amino pyridiniumyl)-hexyl)thiophene] (P3(BAP)HT; E),
2,5-diyl-poly[3-(6-(4-phenylpyridiniumyl)-hexyl)thiophene] (P3(4PP)HT; F),
2,5-diyl-poly[3-(6-(4-(diphenylmethyl)pyridiniumyl)-hexyl)thiophene](P3(DPMP)HT; G),
2,5-diyl-poly[3-(6-(3-phenylpyridin iumyl)-hexyl)thiophene] (P3(3PP)HT; H),
2,5-diyl-poly[3-(6-(4-(7-hexyl-benzo[lmn][3,8]phenanthrolin-2-yl-1,3,6,8-tetraone)pyridiniumyl)-hexyl)thiophene] (P3(HBPTP)HT; I), and
2,5-diyl-poly[3-(6-(4-(3-phenylpropyl)pyridiniumyl)-hexyl)thiophene] (P3(PPP)HT; J).

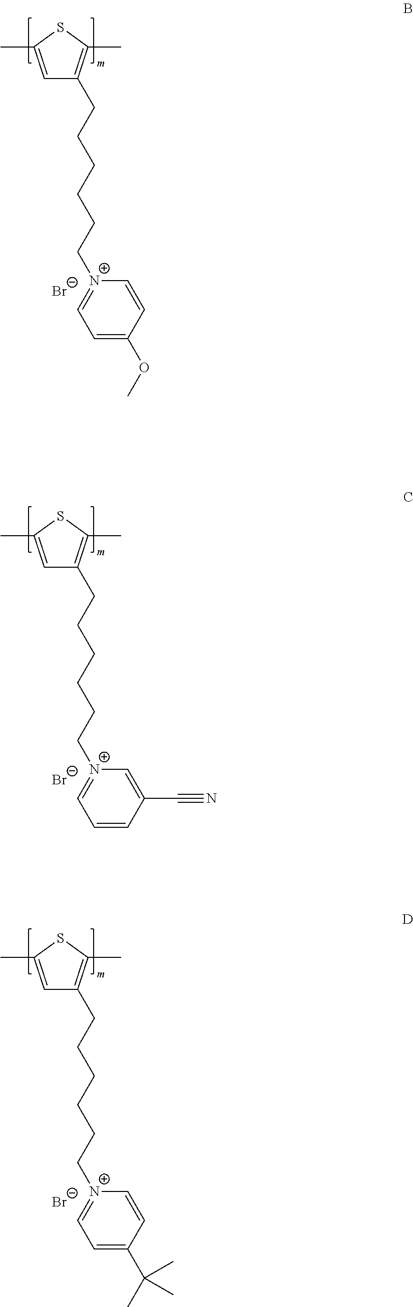

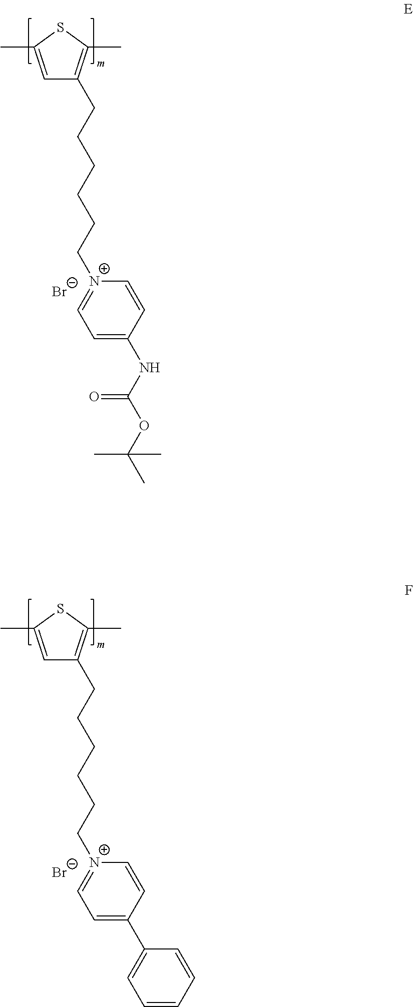

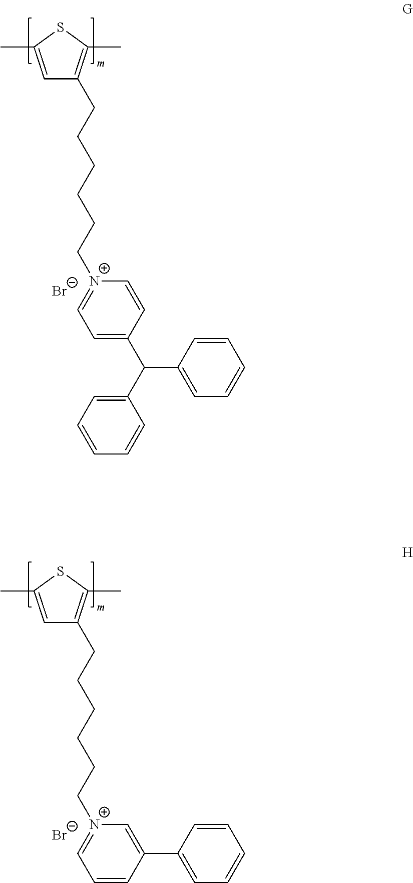

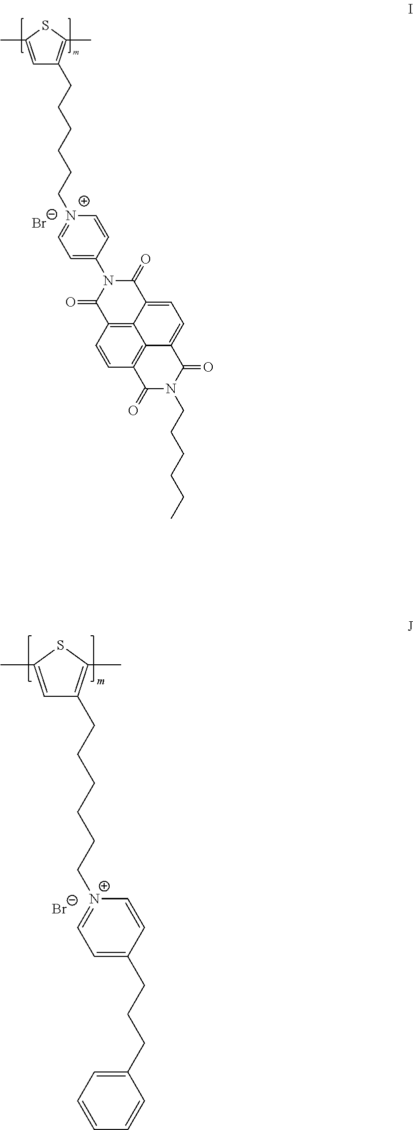

The hexyl chain (on the naphthalene diimide moiety) on derivative I may be varied to be a shorter or longer or a branched alkyl or alkene chain, or removed altogether. The carbon chain may be further functionalized with a carboxylic acid, tertiary amine, thiol, halogen, thiophene, pyridine or phenyl. In another embodiment, the two-ring naphthalene core may be replaced with a five-ring perylene core, which may be unsubstituted or substituted, for example, with methyl, alkyl or halogen.

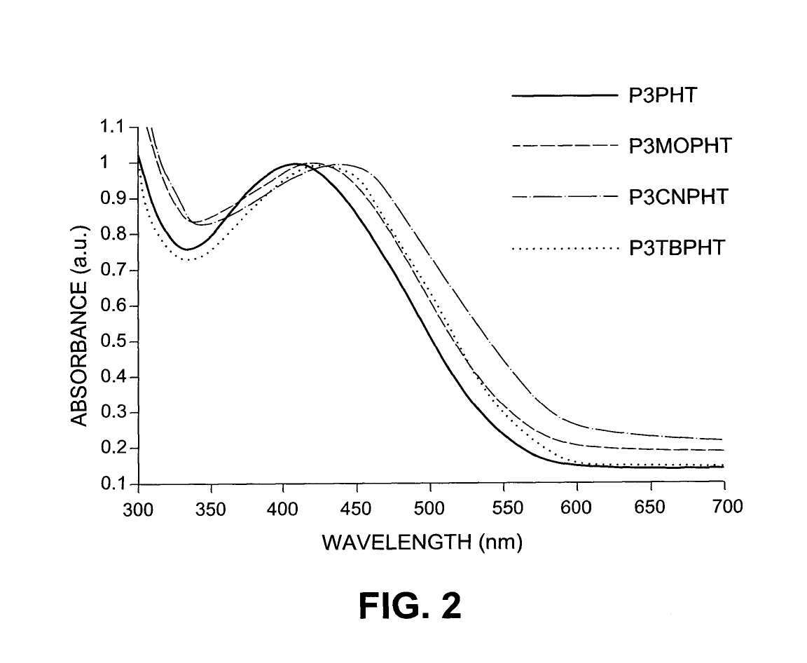

The UV-visible light absorbance characteristics of these derivatives may be very similar. As shown in FIG. 2, solutions containing the derivatives may have very similar λₘₐₓ values. As shown, the λₘₐₓ value for P3CNPHT is slightly red-shifted and the band gap is smaller.

The FSP derivatives of the present invention may be synthesized by a post-polymerization modification of the alkyl side-chains of regioregular or regiorandom poly[3-(6-X-hexyl)thiophene] where X comprises a leaving group (7). In one embodiment, the leaving group is bromo and the starting material is P3BHT as shown in FIG. 1. Other leaving groups may be suitable such as other halogens/halides. The FSPs of the present invention result from a quaternization reaction of a functionalized pyridine with P3BHT. ¹H NMR spectroscopy may be used to assess the extent of quaternization.

In another aspect, the invention comprises the application of FSPs as a cationic counterpart to anionic (PEDOT:PSS)⁻ to produce hybrid coatings on ITO electrodes. In one embodiment, the FSPs may be used in an electrostatic layer-by-layer (LbL) assembly method with colloidal suspensions of (PEDOT:PSS)⁻. In another embodiment, the FSPs may be used in a modification of an electrochemically prepared anionic (PEDOT: PSS)⁻ coating on ITO. In both motifs, the electronic properties of the ITO are modulated allowing the electrode to function as a cathode in inverted P3HT:PCBM solar cells.

(PEDOT:PSS)⁻ Na⁺ is a polymer blend of cationic and conducting PEDOT that is charge-balanced by anionic and insulating PSS. The strongly coupled PEDOT:PSS is rich in PSSNa with a typical PEDOT:PSS ratio of approximately 1:6, and hence the (PEDOT:PSS)⁻ Na⁺ complex bears an overall negative charge in aqueous solution.

Typically, a commercially available colloidal suspension of (PEDOT:PSS)⁻ Na⁺ [(cPEDOT:PSS)⁻ Na⁺] is applied to ITO electrodes by spin-coating from aqueous dispersions, yielding (cPEDOT:PSS)⁻ Na⁺ films that are often employed as hole-collecting interfacial layers at the ITO anode. Starting with a substrate that has a charged surface, electrostatic layer-by-layer (LbL) growth is accomplished by alternating exposure to cationic and anionic polymer solutions, and it deposits films of controlled thickness and composition. Given the cationic nature of FSPs, LbL assembly with (cPEDOT:PSS)⁻ Na⁺ provides a route to FSP/cPEDOT:PSS films on ITO. To preliminarily test for the requisite electrostatic association between any embodiment of an FSP⁺ and (cPEDOT:PSS)⁻, samples of the two aqueous solutions may be mixed. If an instantaneous precipitation is observed on mixing, a strong electrostatic binding and aggregation of the anionic and cationic polymer components may be inferred.

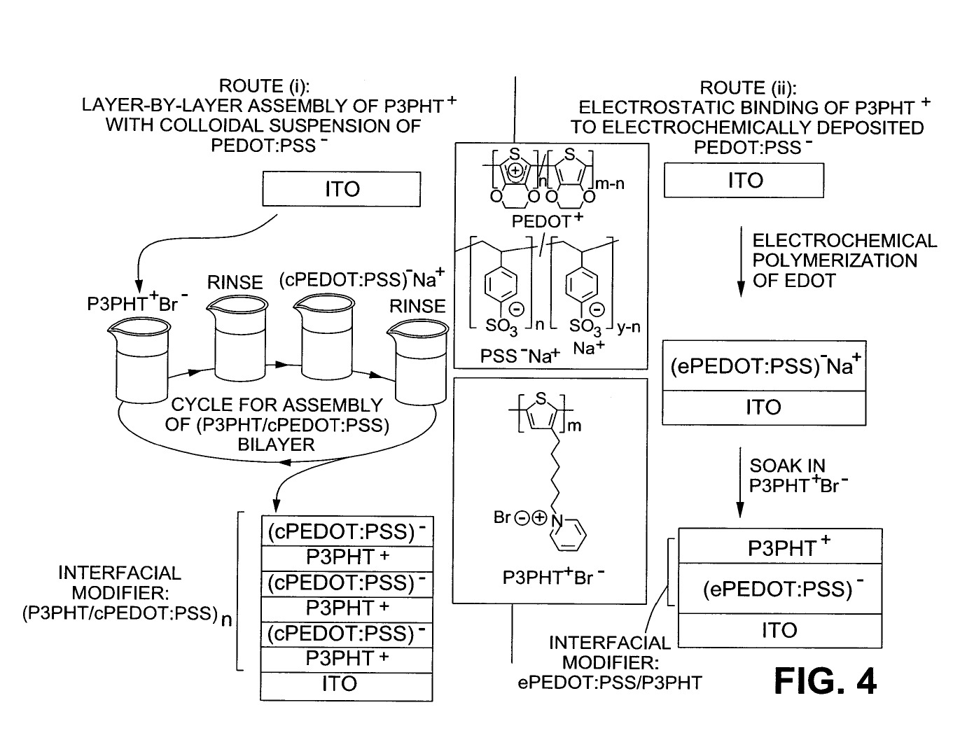

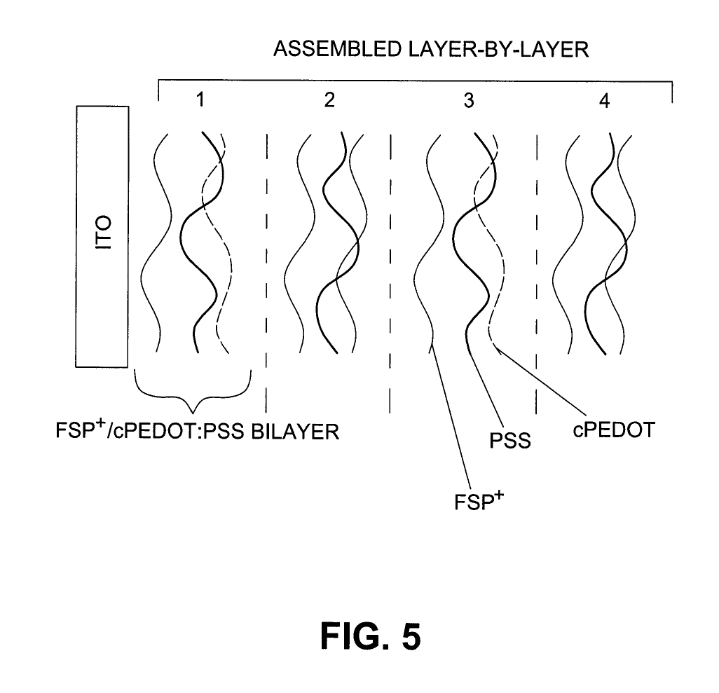

Alternatively, by using freshly cleaned ITO as an initial substrate, an electrostatic LbL deposition of these polymers is possible. On exposure of the ITO surface to an aqueous solution of FSP⁺, the cationic polymer electrostatically binds to the ITO surface. Due to charge overcompensation by FSP⁺, the rinsed platform becomes positively charged and, consequently, strongly associates with (cPEDOT:PSS)⁻ in the subsequent immersion step. Following a thorough rinse to remove physisorbed material as well as the electrostatic binding byproduct, NaBr, the formation of the first FSP/cPEDOT:PSS⁻ bilayer is complete. Due to charge overcompensation, the surface bears overall net negative charge permitting the formation of subsequent bilayers by further reiterating the cycle depicted in route (i) in FIG. 4. For n repeats of the LbL cycle, a (FSP/cPEDOT:PSS)ₙ multilayer film of n bilayers is produced. It is unlikely that each bilayer corresponds to a distinct layer system with abrupt interfaces but rather a disordered interpenetrating network of polymeric components as shown schematically in FIG. 5, where the dashed lines show the boundaries between bilayers.

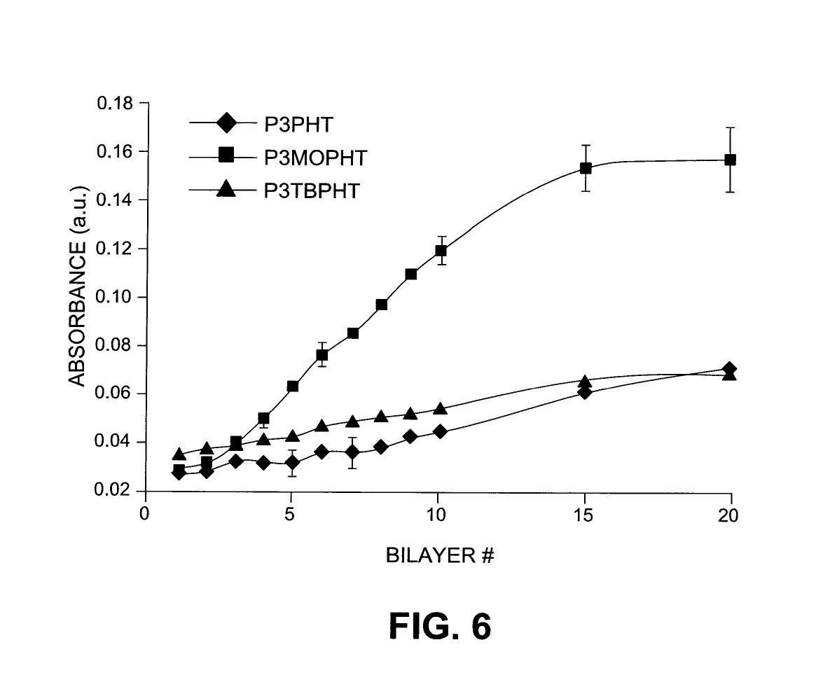

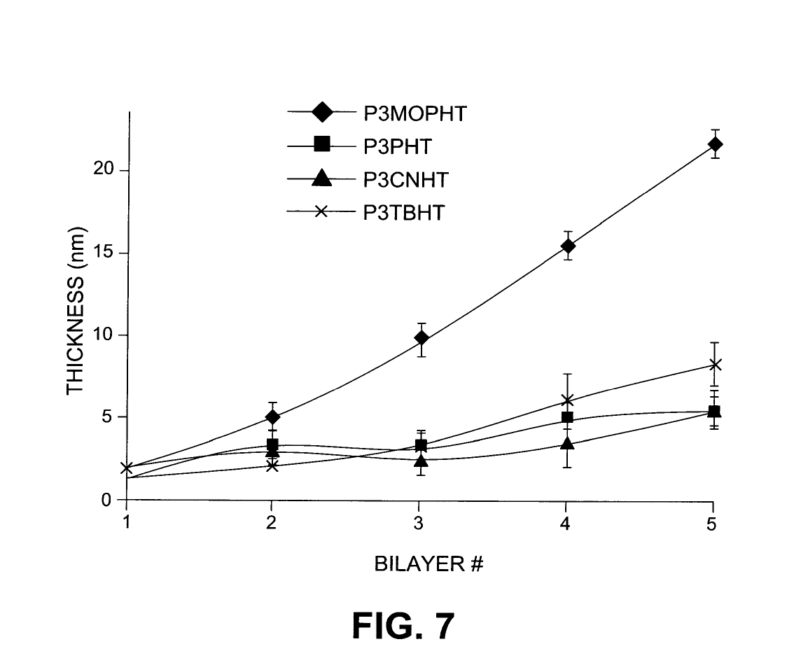

With an ongoing deposition of films with increasing bilayer number n, there is a corresponding increase in the optical density. As shown in FIG. 6, optical absorbance increases with bilayer number. Also, thickness increases with bilayer number, as shown in FIG. 7.

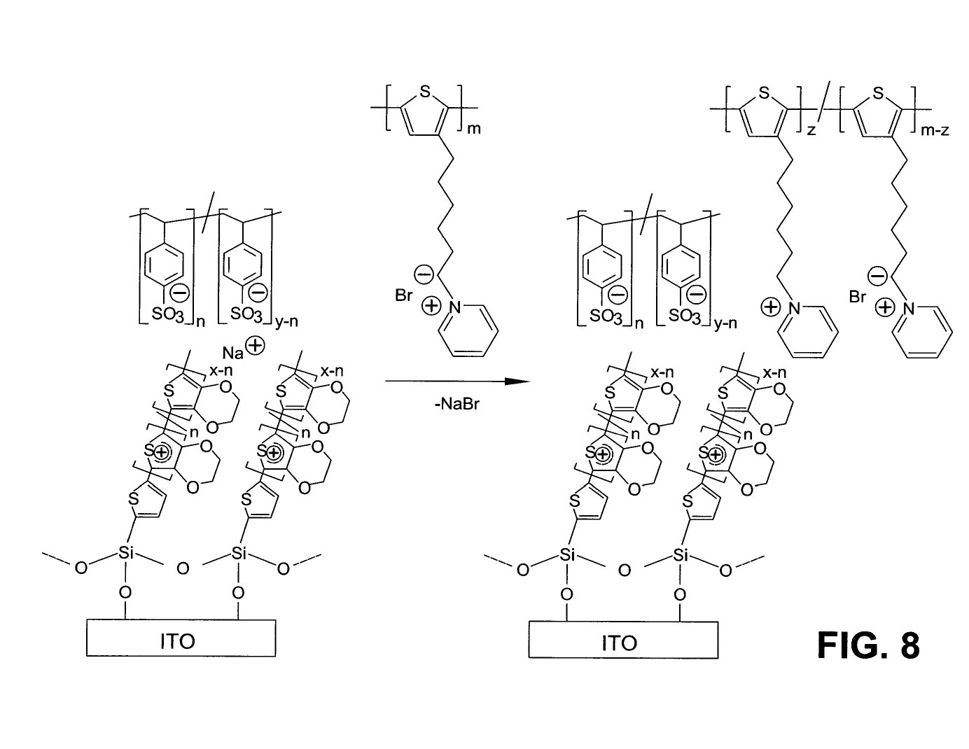

An electrochemical route to the interfacial modifiers of the present invention may involve the use of thienylsilane-modified ITO. The electrode surface consists of a hydrolyzed layer of triethoxy-2-thienylsilane that is used as a “seed layer” for the nucleation and electrochemical polymerization of EDOT from PSSNa electrolyte. The chemical structure of the modified ITO electrode is depicted in FIG. 8. In one embodiment, the electrochemical deposition procedure is analogous to the formation of a half-bilayer with (cPEDOT:PSS), while soaking in an FSP completes the bilayer structure by a similar mechanism. This process is shown schematically in route (ii) in FIG. 4. The binding of FSP⁺ to films of (ePEDOT:PSS) results in differences in the optical absorbance of the samples.

### EXAMPLES

The following examples are provided to illustrate specific embodiments of the claimed invention, and not to limit the claimed invention in any manner.

### Example 1

### Reagents and Physical Measurements

Triethoxy-2-thienylsilane, EDOT, PSSNa (MW=70 000 Da), dimethyformamide (DMF), tetrahydrofuran (THF), dichloromethane, isopropyl alcohol, and o-dichlorobenzene may be used as commercially available products. P3BHT (Mₙ=13 300 Da, PDI=1.86) is also commercially available from Polymer Source and may be used without further purification. Regioregular P3HT and PCBM is also commercially available from Rieke Metals and American Dye Source Inc, respectively. A commercially available colloidal suspension of (cPEDOT:PSS)⁻Na⁺ is available from H.C. Stark (Heraeus Clevios P VP Al4083). ITO coated glass substrates (8-12 ohms/square are available from Delta Technologies, Ltd. The ITO coated glass substrates were cleaned by sequential 10 min ultrasonication in dichloromethane, water, and isopropyl alcohol, and were further cleaned by exposure to a 10 min air plasma at 0.1 mTorr (Harrick Plasma, PDC 32 G, 18 W) immediately prior to use.

### Example 2

### Synthesis of FSPs

The synthesis is conducted according to a modified protocol of the procedures outlined by Xue et al. and Gutakeret et al. Briefly, and as an example, a functionalized pyridine may be added to a stirred 3:2 (v/v) DMF:THF solution of P3BHT. The mixture is stirred at 70° C. under an Ar atmosphere for 72 h. After removal of most of the solvent, the residue is precipitated in THF (50 mL). The precipitate is collected by centrifuging at 10 000 rpm for 30 min, and the extract dried under vacuum at 50° C. to obtain FSP as a solid.

### Example 3

### Preparation of (FSP/cPEDOT:PSS)ₙ Coated ITO Substrates

For the deposition of FSP/cPEDOT:PSS bilayers on ITO, a LbL method in air may be used. Freshly cleaned ITO substrates are first immersed in a 95:5 (v/v) H₂O:DMF solution of FSP⁻Br⁺ for 5 min, rinsed with deionized water, then transferred to a 0.8 wt % aqueous solution of (cPEDOT:PSS)⁻Na⁺ for 5 min. Rinsing with deionized water completes one bilayer formation cycle. After performing a chosen number of cycles, completed films are spin dried at 3000 rpm for 60 s.

### Example 4

### Preparation of (ePEDOT:PSS/P3PHT) Coated ITO Substrates

Cleaned ITO coated glass substrates are evacuated for 30 min in a desiccator containing an open vessel of triethoxy-2-thienylsilane. Substrates are left under static vacuum for 18 h and then exposed to ambient atmosphere for 2 h prior to use. A potentiostatic method may be used for the electrochemical deposition of (ePEDOT:PSS)⁻Na⁺ on thienylsilane-modified ITO working electrode using a solution of EDOT (10 mM) and PSSNa (20 mM) as the monomer and supporting electrolyte, respectively. The film thickness is controlled by monitoring the electrical charge passed during the growth process. The films are thoroughly rinsed with deionized water (18 MΩ·cm), followed by spin drying at 3000 rpm for 60 s. Typically, substrates are then immersed in a 95:5 (v/v) H₂O:DMF solution of P3RHT⁻Br⁺ for 5 h in air, rinsed with copious amounts of deionized water, and then spin dried as above.

### Example 5

### Photovoltaic Device Fabrication

The bulk heterojunction polymer/fullerene photovoltaic devices consist of blended films of regioregular P3HT and PCBM sandwiched between a transparent cathode and a reflective anode. The cathode consists of ITO coated glass substrates modified with P3RHT⁻Br⁺ and either i) (cPEDOT:PSS)⁻ or ii) (ePEDOT:PSS)⁻. All modified PEDOT:PSS coated ITO substrates are further dried at 110° C. for 10 min under inert atmosphere immediately prior to coating with active layer. P3RHT is dissolved in o-dichlorobenzene to make a 17 mg/mL solution, followed by blending with an equivalent mass of PCBM. The blend is stirred for 6 h at 50° C. in a glove box before spin-casting. The P3HT/PCBM solution is applied in air by spin coating from solution at 600 rpm for 60 s and allowing the films to dry over the course of 15 min. The anode consists of a combination of 10 nm of V₂O₅ (Sigma-Aldrich, 99.99%) with 80 nm of Al (Kurt J. Lesker, 99.99%) that is applied under high vacuum conditions by thermal evaporation. OPV devices may be stored in a glove box or vacuum chamber between intermittent assessments of their solar cell performance in air.

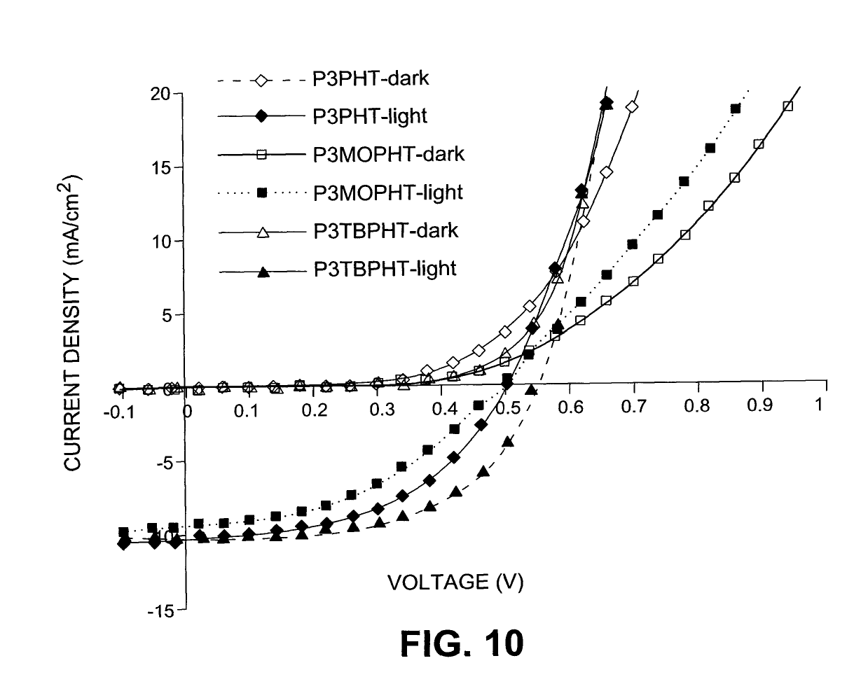

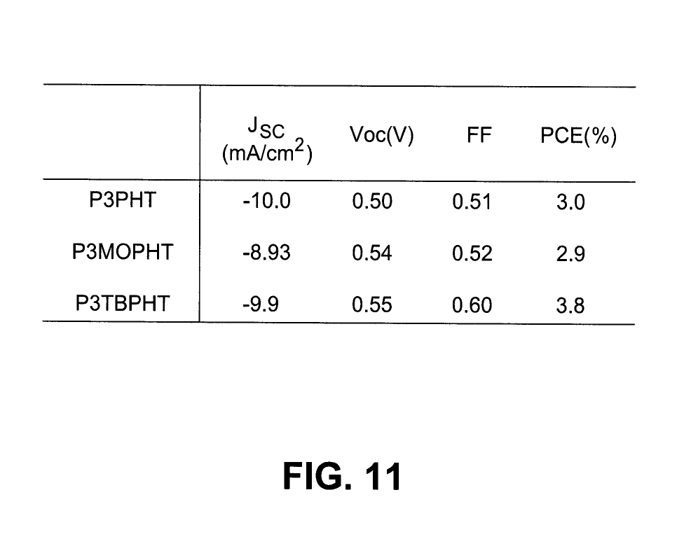

Photovoltaic device testing may be performed at ambient atmosphere and temperature under simulated AM 1.5 G irradiation using a xenon lamp-based solar simulator (Oriel 91191 1000 W Solar Simulator) (FIGS. 10 and 11). The testing irradiance may be set with an NREL calibrated Si reference cell (model PVM 31, PV Measurements Inc.). Device characterization may be performed using a computer-controlled Keithley 2400 source meter.

### Example 6

### Cyclic Voltammetry Analysis

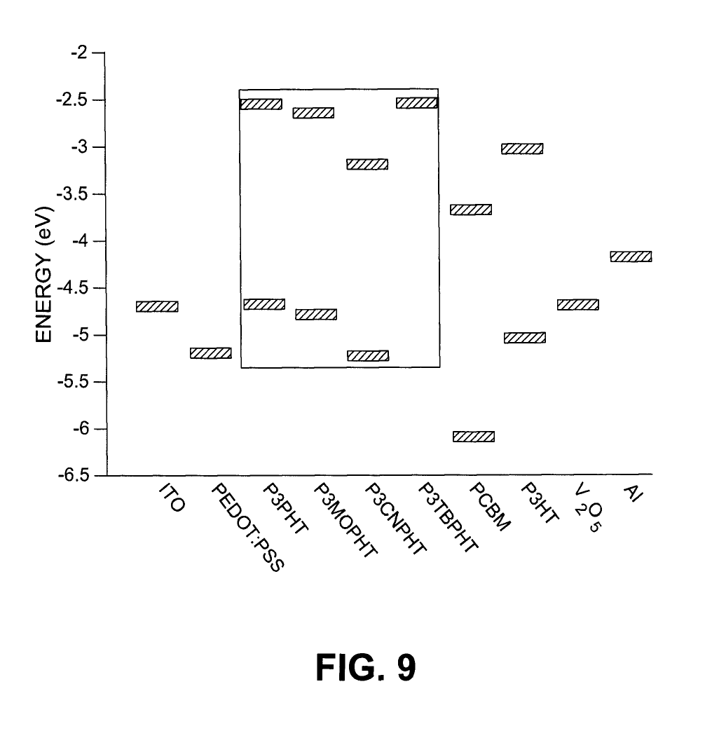

Films of polymer were subjected to cyclic voltammetry analysis to determine the energy level at the onset of oxidation (HOMO level) and at the onset of reduction (LUMO level). Results are shown in FIG. 9. The polymers show appropriate energy levels for charge transport.

As will be apparent to those skilled in the art, various modifications, adaptations and variations of the foregoing specific disclosure can be made without departing from the scope of the invention claimed herein.

### REFERENCES

(1) Tang, C. W. Appl. Phys. Lett. 1986, 48, 183-184.
(2) Sariciftci, N. S.; Smilowitz, L.; Heeger, A. J.; Wudl, F. Science 1992, 258, 1474-1476.
(3) Yu, G.; Pakbaz, A. J.; Heeger, A. J. Appl. Phys. Lett. 1994, 64, 3422-3424.
(4) Halls, J. J. M.; Walsh, C. A.; Greenham, N. C.; Marseglia, E. A.; Friend, R. H.; Moratti, S. C.; Holmes, A. B. Nature 1995, 376, 498-500.
(5) Brabec, C. J.; Cravino, A.; Meissner, D.; Sariciftci, N. S.; Fromherz, T.; Rispens, M. T.; Sanchez, L.; Hummelen, J. C. Adv. Funct. Mater. 2001, 11, 374-380.
(6) Shaheen, S. E.; Radspinner, R.; Peyghambarian, N.; Jabbour, G. E. Appl. Phys. Lett. 2001, 79, 2996-2998.
(7) Xue, J.; Uchida, S.; Rand, B. P.; Forrest, S. R. Appl. Phys. Lett. 2004, 84, 3013-3015.
(8) Coakley, K. M.; McGehee, M. D. Chem. Mater. 2004, 16, 4533-4542.
(9) Spanggaard, H.; Krebs, F. C. Sol. Energy Mater. Sol. Cells 2004, 2004, 125-146.
(10) Roncali, J. Chem. Soc. Rev. 2005, 34, 483-495.
(11) Gledhill, S. E.; Scott, B.; Gregg, B. A. J. Mater. Res. 2005, 20, 3167-3179.
(12) Blom, P. W. M.; Mihailetchi, V. D.; Koster, L. J. A.; Markov, D. E. Adv. Mater. 2007, 19, 1551-1566.
(13) Krebs, F. C.; Spanggard, H.; Kjaer, T.; Biancardo, M.; Alstrup, J. Mater. Sci. Eng., B 2007, 138, 106-111.
(14) Lungenschmied, C.; Dennler, G.; Neugebauer, H.; Sariciftci, N. S.; Glatthaar, M.; Meyer, T.; Meyer, A. Sol. Energy Mater. Sol. Cells 2007, 91, 379-384.
(15) Saunders, B. R.; Turner, M. L. Adv. Coll. Inter. Sci. 2008, 138, 1-23.
(16) Thompson, B. C.; Fréchet, J. M. Angew. Chem. Int. Ed. 2008, 47, 58-77.
(17) Waldauf, C., Morana, M., Denk, P., Schilinsky, P., Coakley, K., Choulis, S. A., Brabec, C. J., Applied Physics Letters, 89(23), 233517, (2006).
(18) Glatthaar, M., Niggemann, M., Zimmermann, B., Lewer, P., Riede, M., Hinsch, A., Luther, J., Thin Solid Films, 491(1-2), 298, (2005).
(19) Sahin, Y., Alem, S., De Bettignies, R., Nunzi, J.-M., Thin Solid Films, 476, 340-343, (2005).
(20) Zhao, D. W., Liu, P., Sun, X. W., Tan, S. T., Ke, L., Kyaw, A. K. K., Appl. Phys. Lett., 95(15), 153304, (2009).
(21) Zimmermann, B., Wurfel, U., Niggemann, M., Sol. Ener. Mater. & Sol. Cells, 93, 491, (2009).
(22) Roman, L. S.; Mammo, W.; Pettersson, L. A. A.; Anderson, M. R.; Inganas, O. Adv. Mater. 1998, 10, 774-777.
(23) Liao, H.-H.; Chen, L.-M.; Xu, Z.; Li, G.; Yang, Y. Appl. Phys. Lett. 2008, 92, 173303.
(24) White, M. S.; Olson, D. C.; Shaheen, S. E.; Kopidakis, N.; Ginley, D. S. Appl. Phys. Lett. 2006, 89, 143517-143519.
(25) Ho, P. K. H.; Kim, J.-S.; Burroughes, J. H.; Becker, H.; Li, S. F. Y.; Brown, T. M.; Cacialli, F.; Friend, R. H. Nature 2000, 404, 481-484.
(26) DeLongchamp, D. M.; Kastantin, M.; Hammond, P. T. Chem. Mater. 2003, 15, 1575-1586.
(27) Wakizaka, D.; Fushimi, T.; Ohkita, H.; Ito, S. Polymer 2004, 45, 8561-8565.
(28) Sakai, N.; Prasad, G.; Ebina, Y.; Takada, K.; Sasaki, T. Chem. Mater. 2006, 18, 3596-3598.
(29) DeLongchamp, D.; Hammond, P. T. Adv. Mater. 2009, 13, 1455-1459.
(30) Rider, D. A.; Worfolk, B. J.; Harris, K. D.; Lalany, A.; Shahbazi, K.; Fleischauer, M. D.; Brett, M. J.; Buriak, J. M. Adv. Funct. Mater. 2010, 20(15), 2404-2415.
(31) Gutacker, A.; Adamczyk, S.; Helfer, A.; Garner, L. E.; Evans, R. C.; Fonseca, S. M.; Knaapila, M.; Bazan, G. C.; Burrows, H. D.; Scherf, U. J. Mater. Chem., 2010, 20, 1423-1430.
(32) G. Tu, H. Li, M. Forster, R. Heiderhoff, L. J. Balk, R. Sigel, U. Scherf, Small, 2007, 3, 1001-1006.
(33) Gutacker, A.; Koenen, N.; Scherf, U.; Adamczyk, S.; Pina, J.; Fonseca, S. M.; Valente, A. J. M.; Evans, R. C.; de Melo, J. S.; Burrows, H. D.; Knaapila, M. Polymer, 2010, 51 (9), 1898-1903.

1. A functionalized semiconducting polymer with the following generalized structure: 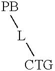
wherein PB is a semiconducting polymer backbone selected from any one of poly(p-phenylene vinylene) (PPV), poly(benzodithiophene-alt-[3,4-c]thienopyrrole-4,6-dione) (PBDTTPD), poly(2,7-carbazole-alt-5,5-di-2-thienylbenzothiadiazole (PCDTBT), poly(thieno[3,4-b]thiophene-alt-benzodithiophene) (PTB(1-8)), poly(fluorene-alt-bithiophene) (FT2), poly(dithienosilole-alt-[3,4-c]thienopyrrole-4,6-dione) (PDTSTPD), poly(dithieno(3,2-b:2′,3′-d)silole)-alt-benzothiadiazole) (PSBTBT) and poly(1,4-diketopyrrolopyrrole) (DPP) or functional derivatives thereof or where PB is any one of polythiophene or polyacetylene or functional derivatives thereof;
L is a single bond, C, or C2-C14 alkyl, alkoxy or alkenyl chain, and CTG is a cationic terminal group selected from a quaternary ammonium cation providing a net positive charge in aqueous solutions or 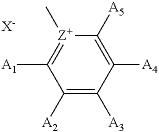
where Z is either nitrogen or phosphorus, A₁, A₂, A₃, A₄ and A₅ are each independently selected from hydrogen, cyano, phenyl, C1-C6 alkoxy, a C1-C6 linear or branched alkyl optionally substituted with one or two phenyl groups, carbamate, a C1-C6 linear or branched alkyl ester optionally substituted with one or two phenyl groups, and 7-hexyl-benzo[lmn][3,8]phenanthrolin-2-yl-1,3,6,8-tetraone, and X is a counterion.

2. The functionalized semiconducting polymer as in claim 1 with the following generalized structure: 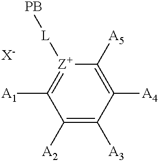
wherein PB is a semiconducting polymer backbone selected from any one of poly(p-phenylene vinylene) (PPV), poly(benzodithiophene-alt-[3,4-c]thienopyrrole-4,6-dione) (PBDTTPD), poly(2,7-carbazole-alt-5,5-di-2-thienylbenzothiadiazole (PCDTBT), poly(thieno[3,4-b]thiophene-alt-benzodithiophene) (PTB(1-8)), poly(fluorene-alt-bithiophene) (FT2), poly(dithienosilole-alt-[3,4-c]thienopyrrole-4,6-dione) (PDTSTPD), poly(dithieno(3,2-b:2′,3′-d)silole)-alt-benzothiadiazole) (PSBTBT) and poly(1,4-diketopyrrolopyrrole) (DPP) or functional derivatives thereof or where PB is any one of polythiophene or polyacetylene or functional derivatives thereof;
and wherein L is a single bond, C, or C2-C14 alkyl, alkoxy or alkenyl chain, Z is either nitrogen or phosphorus, A₁, A₂, A₃, A₄ and A₅ are each independently selected from hydrogen, cyano, phenyl, C1-C6 alkoxy, a C1-C6 linear or branched alkyl optionally substituted with one or two phenyl groups, carbamate, a C1-C6 linear or branched alkyl ester optionally substituted with one or two phenyl groups, and 7-hexyl-benzo[lmn][3,8]phenanthrolin-2-yl-1,3,6,8-tetraone and X is a counterion.

3. The functionalized semiconducting polymer as in claim 1 wherein A₁, A₂, A₃, A₄ and A₅ are not all hydrogen and wherein the polymer backbone is not polythiophene and the linker L is not C6 alkyl.

4. The functionalized semiconducting polymer as in claim 1 wherein the polymer backbone is polythiophene.

5. The functionalized semiconducting polymer as in claim 1 wherein the polymer backbone is polyacetylene.

6. The functionalized semiconducting polymer as in claim 1 wherein the polymer backbone is PBDTTPD.

7. The functionalized semiconducting polymer as in claim 1 wherein the polymer backbone is PCDTPT.

8. The functionalized semiconducting polymer as in claim 1 wherein the polymer backbone is PDTSTPD.

9. The functionalized semiconducting polymer as in claim 1 wherein the polymer backbone is PSBTBT.

10. The functionalized semiconducting polymer as in claim 1 wherein L is a C3-C8 alkyl, alkoxy or alkenyl.

11. The functionalized semiconducting polymer as in claim 1 wherein the counterion is any one of a halide, sulphate, sulphonate, carboxylate, perchlorate, nitrate, carbonate, hydroxide, benzoate, tosylate, or acetate ion.

12. The functionalized semiconducting polymer as in claim 1 wherein the counterion is a halogen chosen from bromine, chlorine or iodine.

13. The functionalized semiconducting polymer as in claim 2 wherein Z is nitrogen.

14. The functionalized semiconducting polymer as in claim 2 wherein Z is phosphorus.

15. The functionalized semiconducting polymer as in claim 2 wherein A3, A4 and A5 are independently selected from hydrogen, cyano, phenyl, C1-C8 alkoxy, C1-C8 linear or branched alkyl optionally substituted with one or two phenyl groups, carbamate, C1-C6 linear or branched alkyl ester optionally substituted with one or two phenyl groups, and 7-hexyl-benzo[lmn][3,8]phenanthrolin-2-yl-1,3,6,8-tetraone.

16. The functionalized semiconducting polymer as in claim 2 selected from any one of:
2,5-diyl-poly[3-(6-(4-methoxy pyridiniumyl)-hexyl)thiophene] (P3(MOP)HT);
2,5-diyl-poly[3-(6-(3-cyano pyridiniumyl)-hexyl)thiophene] (P3(CNP)HT);
2,5-diyl-poly[3-(6-(4-tert-butylpyridiniumyl)-hexyl)thiophene] (P3(TBP)HT);
2,5-diyl-poly[3-(6-(4-boc-amino pyridiniumyl)-hexyl)thiophene] (P3(BAP)HT);
2,5-diyl-poly[3-(6-(4-phenylpyridiniumyl)-hexyl)thiophene] (P3(4PP)HT;
2,5-diyl-poly[3-(6-(4-(diphenylmethyl)pyridiniumyl)-hexyl)thiophene] (P3(DPMP)HT;
2,5-diyl-poly[3-(6-(3-phenylpyridiniumyl)-hexyl)thiophene] (P3(3PP)HT;
2,5-diyl-poly[3-(6-(4-(7-hexyl-benzo[lmn][3,8]phenanthrolin-2-yl-1,3,6,8-tetraone)pyridiniumyl)-hexyl)thiophene] (P3(HBPTP)HT); and
2,5-diyl-poly[3-(6-(4-(3-phenylpropyl)pyridin iumyl)-hexyl)thiophene] (P3(PPP)HT).

17. A method of forming an interfacial modifier comprising the step of forming a polymer hybrid with a functionalized semiconducting polymer of claim 1 and (PEDOT:PSS)⁻ or a functional equivalent thereof.

18. An organic photovoltaic device comprising a cathode including an interfacial modifier prepared by the method of claim 17.

19. A method of forming an interfacial modifier by layer by layer (LbL) deposition comprising the steps of:
a. applying a functionalized semiconducting polymer (FSP⁺) of claim 1 to a conductive electrode to form a first half bilayer;
b. applying (PEDOT:PSS)—Na⁺ or a functional equivalent thereof to the first half bilayer to yield a first bilayer comprising a (PEDOT:PSS)⁻ film on the first half bilayer; and,
c. repeating steps a) and b) to a desired number of bilayers.

20. A method of forming an interfacial modifier by layer by layer (LbL) deposition comprising the steps of:
a. applying (PEDOT:PSS)⁻ Na⁺ or a functional equivalent thereof electrochemically to a conductive electrode to yield a first half bilayer;
b. applying a functionalized semiconducting polymer (FSP⁺) of claim 1 to the first half bilayer to form a first bilayer;
c. repeating steps a) and b) to a desired number of bilayers.
